(19) United States
(12) Patent Application Publication
(10) Pub. No.: US 2007/0114010 A1
(43) Pub. Date: May 24, 2007

(54) Liquid cooling for backlit displays

(76) Inventors: Girish Upadhya, Austin, TX (US); Mark Munch, Los Altos, CA (US)

Correspondence Address: HAVERSTOCK & OWENS LLP, 162 NORTH WOLFE ROAD, SUNNYVALE, CA, 94086, US

(21) Appl. No.: 11/595,489

(22) Filed: Nov. 8, 2006

Related U.S. Application Data
(60) Provisional application No. 60/735,757, filed on Nov. 9, 2005.

(51) Int. Cl. H01L 23/467

(52) U.S. Cl. 165/121

(57) ABSTRACT

The present invention provides a cooling system for a backlit device. The cooling system has a first heat collector that comprises a micro tube. The first heat collector is for maintaining contact with the backlit device. The cooling system also has a first radiator, a first pump, an interconnecting tubing, a fluid, and optionally a fan and/or a reservoir. The first radiator is for distributing and/or dispersing heat, the first pump is for driving a fluid flow, and the reservoir is for storing the fluid. The interconnect tubing is interposed between the first heat collector, the first radiator, and the first pump to form a closed cooling loop. Some embodiments further provide a method of cooling a backlit device by using such a cooling system.

### RELATED APPLICATIONS

This application claims priority under 35 U.S.C. section 119(e) of co-pending U.S. Provisional Patent Application No. 60/735,757, filed Nov. 9, 2005, and entitled “Liquid Cooling Systems for Backlit LED Display Products,” which is hereby incorporated by reference.

### FIELD OF THE INVENTION

The present invention is related to liquid cooling. Specifically, the present invention is related to providing liquid cooling for backlit displays.

### BACKGROUND OF THE INVENTION

Light emitting diode (LED) technology has been making significant advancement in recent years. The advancement of LED technology has produced numerous applications such as interior and exterior (outdoor) lighting, compact or portable lamps, automotive lights, and also light sources for backlit display systems. In the near future, LED lamps are expected to replace traditional incandescent, halogen, and/or fluorescent lamps (particularly mercury and/or cold cathode flourescent lamps) due to cost and energy savings. Additional advantages of modern LED technology include, for example, brighter colors, more compact lighting solutions, independent color control, and higher reliability. LED based backlit displays, in particular, have advantages in terms of brightness, white balance, and color control. More specifically, LED backlit displays are typically comprised of tri-chromatic LED arrays that are finely tunable for optimum white and color balance.

However, these LED applications generally suffer from high cost and high heat issues. In particular, the color performance of an LED display is a closely related function of junction temperature of the LED arrays. Higher power displays with high brightness capability necessitate the use of higher power LED sources. High power LEDs in turn present significant thermal challenges for traditional methods of cooling. For instance, traditional methods of cooling have difficulty coping with the high heat flux of modern LEDs. Traditional heat pipe designs in particular are bulky, which defeats the small and/or thin form factor advantages of many LED applications. Further, heat pipes are limited in the amount of heat they can move, and also in the distance they can move the heat from the heat source, which negatively impacts the display screen size. Thus, improved thermal design for LED cooling is critical to support the expansion of LED applications.

### SUMMARY OF THE INVENTION

A cooling system for a backlit device includes a first heat collector, a first radiator, a first pump, an interconnect tubing, and a fluid. The first heat collector preferably has a micro structure such as micro channels or micro tubes, and is maintained in contact with the backlit device. The first radiator is for distributing heat and the first pump is for driving a fluid flow. The interconnect tubing is interposed between the first heat collector, the first radiator, and the first pump, to form a closed cooling loop. The fluid is for conducting heat and is sealed within the closed cooling loop.

In some embodiments, a method of cooling a backlit device disposes a heat collector in intimate contact with the backlit device. The heat collector has a fluid. The heat collector is used to collect heat from the backlit device and transfer the heat to a radiator using the fluid. The method rejects the heat from the radiator and recirculates the cooled fluid through the heat collector. The heat collector of some embodiments has a micro structure, and the fluid is pumped through the micro structure.

Preferably, the backlit device comprises an LED backlit flat panel display, and the flat panel display is typically an edge type LED backlit display that generates a high amount of heat per edge. Each edge includes one or more arrays of LEDs. The LEDs typically generate heat in the range of approximately 100 Watts to 1000 Watts. In a particular embodiment, the flat panel display has a thin form factor in the range of approximately 0.5 inches to approximately 4.0 inches in depth.

The first heat collector of some embodiments comprises an extruded multiport tubing in intimate contact with the backlit device. The micro tube of some of these embodiments has internal channels of approximately 0.5 to 5.0 millimeters in width by 0.5 to 5.0 millimeters in height and a wall thickness of approximately 0.5 to 1.0 millimeters. Preferably, the tubes are formed of extruded aluminum, or an alloy of aluminum. Other materials can be used. The first heat collector, in some embodiments, is a manifold that has a plurality of parallel flow vanes. The flow vanes are for directing fluid flow in parallel such that the temperature of the first heat collector is substantially distributed throughout the heat collector and transferred to the fluid in an approximately homogenous manner. In some exemplary implementations, the maximum pitch between the flow vanes is approximately 1.0 to 5.5 millimeters.

Preferably, the first heat collector is bonded to the backlit device by using a thermal interface material (TIM) layer. The TIM layer typically comprise at least one or more of Indium, a metallic coat, a thermal grease, a thermal pad, and/or a phase change material. In some embodiments, the first heat collector is also fastened to the backlit device by using a mechanical means. The mechanical means of these embodiments typically includes one or more of a screw, a bracket, and/or a clamp.

The cooling system of some embodiments further includes a reservoir and/or a fan. When implemented, the reservoir is for storing the fluid within the closed cooling loop, and further, preferably compensates for fluid loss over time. The fan is typically disposed in close proximity to the first radiator and is for rejecting heat from the first radiator.

The radiator of some embodiments has a thin form factor of approximately 15-50 millimeters. The fluid is typically selected from a set of cooling fluids comprising a glycol, an alcohol, a water based solution, and a dielectric solution. The cooling system of some embodiments includes a second heat collector, a plurality of radiators, and/or a plurality of pumps.

### BRIEF DESCRIPTION OF THE DRAWINGS

The novel features of the invention are set forth in the appended claims. However, for purpose of explanation, several embodiments of the invention are set forth in the following figures.

FIG. 1 illustrates a backlit display.

FIG. 2 illustrates a cooling system in accordance with some embodiments of the invention.

FIG. 3 illustrates the cooling system mounted to the backlit display according to some embodiments.

FIG. 4 illustrates a front view of a display with a cooling system according to some embodiments.

FIG. 5 illustrates a side view of the display and the cooling system of FIG. 4.

FIG. 6 illustrates a front view of a display and a cooling system of some embodiments.

FIG. 7 illustrates a side view of the display and cooling system of FIG. 6.

FIG. 8 illustrates a configuration for the cooling system of some embodiments.

FIG. 9 illustrates a heat collector manifold having parallel flow according to some embodiments.

FIG. 10 illustrates the heat collector incorporated into the cooling system of some embodiments.

FIG. 11 illustrates a side view of the heat collector bonded and/or coupled to the layers of an LED array for a backlit display.

FIG. 12 illustrates the flow of fluid across an LED array according to some embodiments of the invention.

FIG. 13 illustrates the steps of a method of cooling a backlit display in accordance with some embodiments of the invention.

### DETAILED DESCRIPTION OF THE INVENTION

In the following description, numerous details are set forth for purpose of explanation. However, one of ordinary skill in the art will realize that the invention can be practiced without the use of these specific details. In other instances, well-known structures and devices are shown in block diagram form in order not to obscure the description of the invention with unnecessary detail.

Overview

Some embodiments of the invention provide a liquid cooling system for an LED backlit device, such as, for example, a flat panel display. These embodiments provide cooling to the LEDs of the display without significantly affecting the thin form factor of the device. The cooling system includes: one or more heat collectors; one or more radiator(s), fan(s), and/or fan radiators that have a small form factor; one or more mechanical pumps; tubing and interconnects to couple the elements of the cooling system together, and complete a closed cooling loop.

The heat collectors are typically made of an extruded multi port tubing which is in intimate contact with the device to collect heat from the device. For an LED backlit device, the LED arrays are traditionally a source of high heat. Accordingly, the heat collector is preferably disposed adjacent the LED arrays. The fluid, by the action of the pump(s), carries heated fluid from the heat collectors to the radiators, where the heat is rejected from the system. The cooled fluid is then (re)circulated by the pump(s) through the heat collectors to continuously draw more heat away from the hot LED array(s). Some embodiments further include a reservoir and/or a volume compensator to adjust the system for fluid loss over time.

Display

LED backlit displays are typically of the “direct” or the “edge” varieties. These categories generally refer to the location of the LEDs with respect to the view screen of the display. In typical LED backlit displays, the LEDs are organized into trichromatic (red, green, blue) arrays. With direct type LED displays, the LED arrays are generally uniformly distributed over the area of the display, such that the heat from the LED arrays is also generally distributed across the surface area of the display. For direct displays, macro or gross cooling solutions that blow cool air over the entire surface area of the distributed LED arrays is often sufficient.

In edge type displays, the LED arrays are grouped and concentrated at the top and bottom edges and/or the right and left edges (the rails) of the display. Optics direct the light from the rails through the remainder of the display. Due to the arrangement of the LED arrays, edge type displays often have cost savings and are advantageously very thin, in comparison to their direct type display counterparts. Some edge type displays, for example, are as thin as 0.50 inches deep, and use many fewer LEDs that are packaged in cost effective groups or arrays (rather than packaged discretely and more expensively as in direct displays). Costlier discretely packaged LEDs allow larger screen sizes for some direct displays, but further add to the thickness of a direct display's form factor. However, the main tradeoff for edge type displays is that the LED arrays must typically be very bright, and further, the heat from the LED arrays is concentrated within a smaller area of the display. Hence, the power consumed and also the heat generated by each concentrated rail of an edge type display is typically on the order of hundreds of Watts.

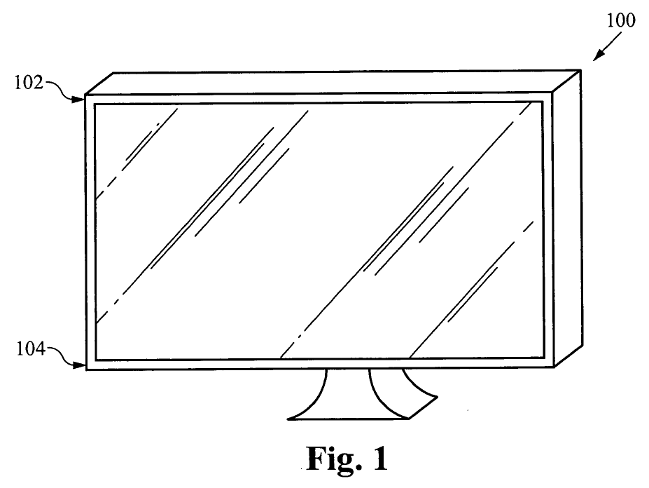

FIG. 1 illustrates an LED backlit display 100 in accordance with some embodiments of the invention. As shown in this figure, the display 100 has a number of LEDs. The LEDs of some embodiments are divided into a top LED array 102 along the top edge of the display 100, and a bottom LED array 104 along the bottom edge of the display 100. One of ordinary skill will recognize that the display 100, the rails, and the LED arrays 102 and 104 of different embodiments has a number of shapes and sizes. For instance, some embodiments have side edge LED array rails, rather than top and bottom edge rails, while some embodiments have multiple arrays per edge. Regardless of the orientation of the rails, and/or the number of LED arrays, the LEDs of the display 100 typically generate a high amount of heat.

Cooling System and Fluid

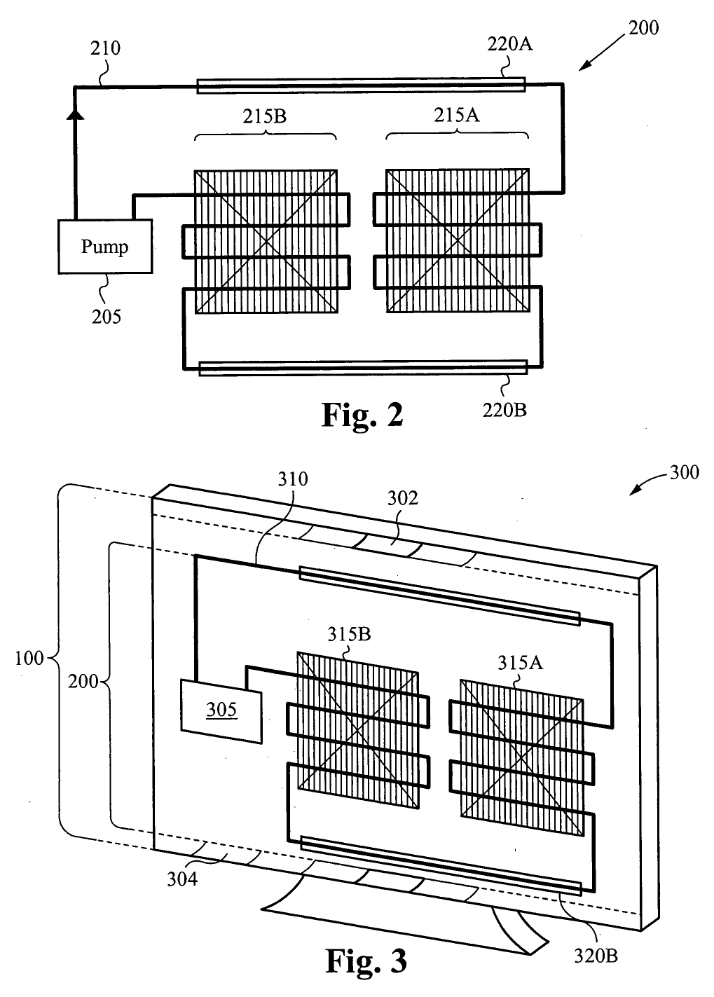

FIG. 2 illustrates a cooling system 200 in accordance with some embodiments of the invention. As shown in this figure, the cooling system 200 has a pump 205 coupled to interconnect tubing 210 that runs from the pump 205 to a first micro tube heat collector 220A.

From the first heat collector 220A, the tubing 210 then directs fluid to a first radiator 215A. In this embodiment, heat is collected by the first micro tube heat collector 220A from a first rail of hot LED array(s), and rejected at the first radiator 215A.

The tubing 210 then couples fluid from the first fan radiator 215A to a second micro tube heat collector 220B, which collects heat from a second rail of hot LEDs. The tubing 210 then couples fluid from the second heat collector 220B to a second radiator 215B, such that heated fluid is transported, by the action of the pump 205, from the second heat collector 220B to the second radiator 215B, where the heat is rejected from the system.

The tubing 210 then returns the fluid from the second radiator 215B to the pump 205. Also shown in FIG. 2, the interconnect tubing 210 of some embodiments forms a closed path from the pump 205, through the heat collectors 220 and radiators 215, and back to the pump 205. In these embodiments, the cooling system 200 typically contains a fluid that is sealed within the closed loop of the system 200. Preferably, the fluid is suitable for cooling, such as, for example, water, a water based solution, a glycol type fluid, an alcohol type fluid, a dielectric solution, and/or another suitable cooling fluid.

Regardless of the type of fluid employed, the cooling system 200 illustrated in FIG. 2 has certain advantages. For instance, the system 200 optimally cools the different edges of a display separately, but still implements a single closed cooling loop, which saves cost and maintains a small form factor for the system 200.

One of ordinary skill will recognize that FIG. 2 is representative, and thus the cooling system 200 of some embodiments includes more that one pump, various numbers of fan radiators, and alternate configurations of interconnect tubing.

Pump and Radiator

The pump 205 typically delivers fluid pressure of approximately two to seven pounds per square inch (PSI), while moving a volume of approximately one to two liters per minute. Some embodiments employ a pump that has a low cost and small dimensions to maintain the small factor of the entire system 200. Quiet operation is an additional design consideration for the pump 205, and hence, the pressure and flow rate of the pump 205 are constrained by these considerations. As described below, the pump 205 is further constrained by the implementation details of the other components, and particularly the heat collector 220, of the system 200. These components of the system 200 of some embodiments are provided by Cooligy, Inc. of Mountain View, Calif. For instance, the pump 205 of some embodiments includes mechanical, electro-kinetic, and/or electro-osmotic pumps. U.S. Pat. No. 6,881,039 B2 entitled “Micro-Fabricated Electrokinetic Pump” and issued Apr. 19, 2005, which is hereby incorporated by reference, describes certain types of pumps in greater detail.

The radiator(s) of some embodiments are actually comprised of two or more radiator elements disposed in certain configurations, such as, a parallel configuration for example, within a single housing. The multiple radiator elements of these embodiments are advantageously implemented with separate fins and fluid pathways for receiving one or more fluid inputs and/or outputs. As shown in FIG. 2, the radiators 215 are disposed side-by-side, and yet separately cool the LED arrays of each distinct edge of the display. This particular configuration allows the relocation of heat to a common locus for rejection from the system 200. Regardless of their particular configuration, the radiators typically operate efficiently while still having a small form factor.

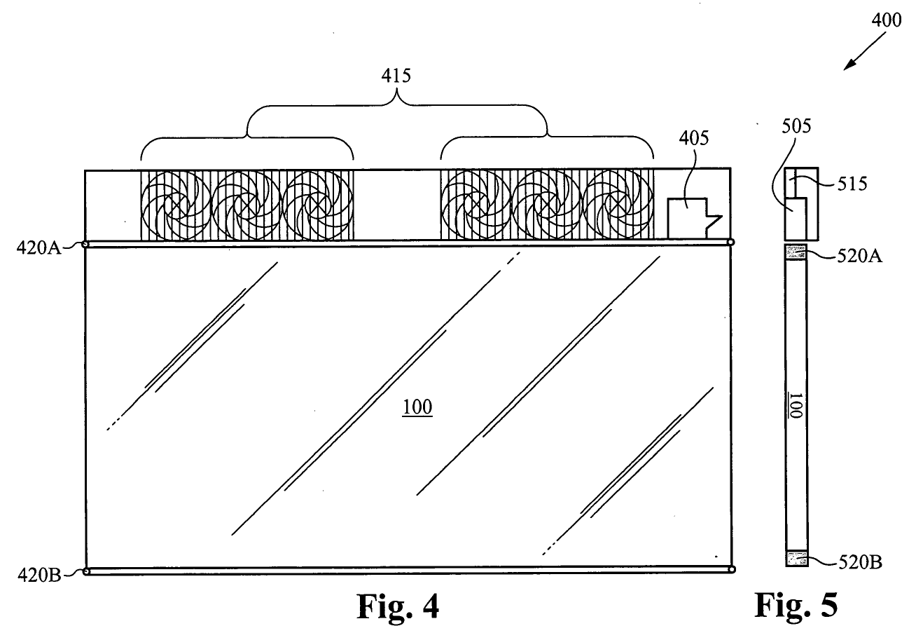

In some embodiments, the radiators are fan radiators that advantageously combine a radiator with a fan in a single unit. To reject sufficient heat for a typical LED backlit display, the fans should move in the range of 5 to 30 cubic feet per minute (cfm). Where a single fan is used, the air flow may cause undesirable noise. Where multiple fans are used such as shown in FIGS. 4, 6, and 8, the air flow from each fan can be less and result in quieter operation of the system.

Typically, heated fluid flows along the fins of the radiator portion. Then, the heat is rejected from the fluid by the air flow generated around the fins by the fan. For instance, the radiators of some embodiments have a thickness of no more than about 15-50 millimeters. Radiators and heat rejection are described in further detail in United States Patent Application Serial No. [not yet assigned—COOL-01304] entitled “Cooling Systems Incorporating Microstructured Heat Exchangers,” filed Oct. 17, 2006, which is incorporated herein by reference.

As used herein, similar numerical identifiers represent similar features between figures. For instance, FIG. 3 illustrates the cooling system 200 illustrated in FIG. 2, mounted to the backlit display 100 illustrated in FIG. 1, according to some embodiments 300 of the invention. As shown in this figure, the interconnect tubing 310 and the first heat collector 320A of the cooling system 300 runs along the top LED array 302 and the second heat collector 320B runs along the bottom LED array 304 of the display 100. Preferably, the heat collectors 320 are in close, intimate contact with the LED arrays 302 and 304, such that the heat generated by the LED arrays 302 and 304 is efficiently transferred to the fluid within the heat collectors 320 and the interconnect tubing 310. As discussed in further detail below, some embodiments maximize thermal transfer between the LED arrays 302 and 304 and the heat collectors 320 by using a combination of mechanical coupling and thermal bonding. In these embodiments, the pump 305 moves the fluid along the interconnect tubing 310 through the fan radiators 315, where heat transfers from the heated fluid to, and is dispersed by, the fan radiators 315, before the cooled fluid returns back to the pump 305 for another pass through the closed cooling system 300.

FIG. 4 illustrates a front view of a display with a cooling system according to certain embodiments of the present invention. As shown in FIG. 4, the cooling system 400 has a pump 405 and a set of fan radiators 415, mounted on top of the display 100. Also shown in FIG. 4, heat collectors 420A and 420B are mounted at the top and bottom of the display 100, respectively. This configuration for the cooling system 400 has minimal impact upon the dimensions of the display 100.

FIG. 5 illustrates a side view of the display 100 with the cooling system 400 of FIG. 4. As shown in FIG. 5 several components of the cooling system 400, such as the pump 505 and the fan radiators 515, fit compactly above the display 100, without significantly affecting its form factor. Also shown in FIG. 5, the heat collectors 520A and 520B have micro tubes that are disposed in close proximity to the edges of the display 100, such that they do not add significantly to its form factor.

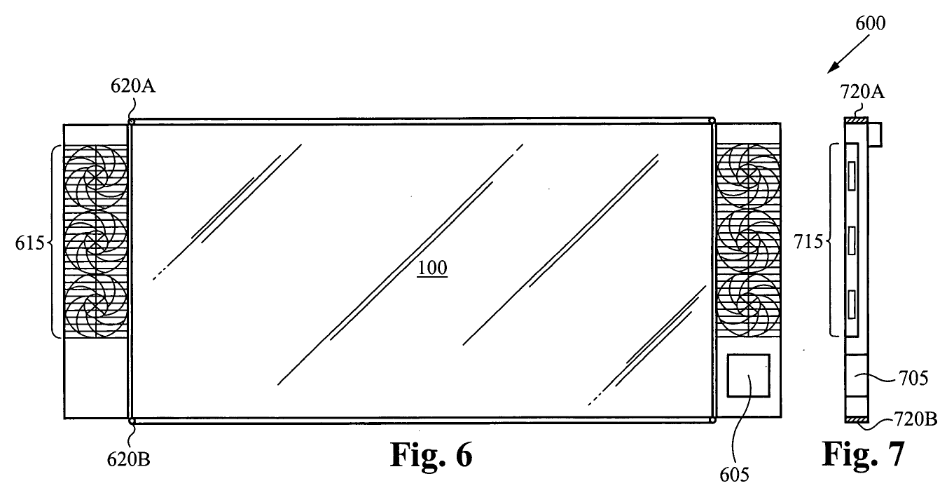

FIG. 6 illustrates a front view of a display and cooling system of alternate embodiments of the present invention. As shown in FIG. 6, the pump 605 and fan radiators 615 are placed on either side of the display 100, while the heat collectors 620 are placed at the top and bottom of the display 100. This alternative configuration also has a minimal impact on the dimensions of the display 100. FIG. 7 illustrates a side view of the display and the cooling system 600 of FIG. 6.

As shown in FIG. 7, several components of the cooling system 600, such as the pump 705 and the fan radiators 715, fit compactly on the side of the display 100. Accordingly, the cooling system 600 of these embodiments does not significantly affect the form factor of the display 100.

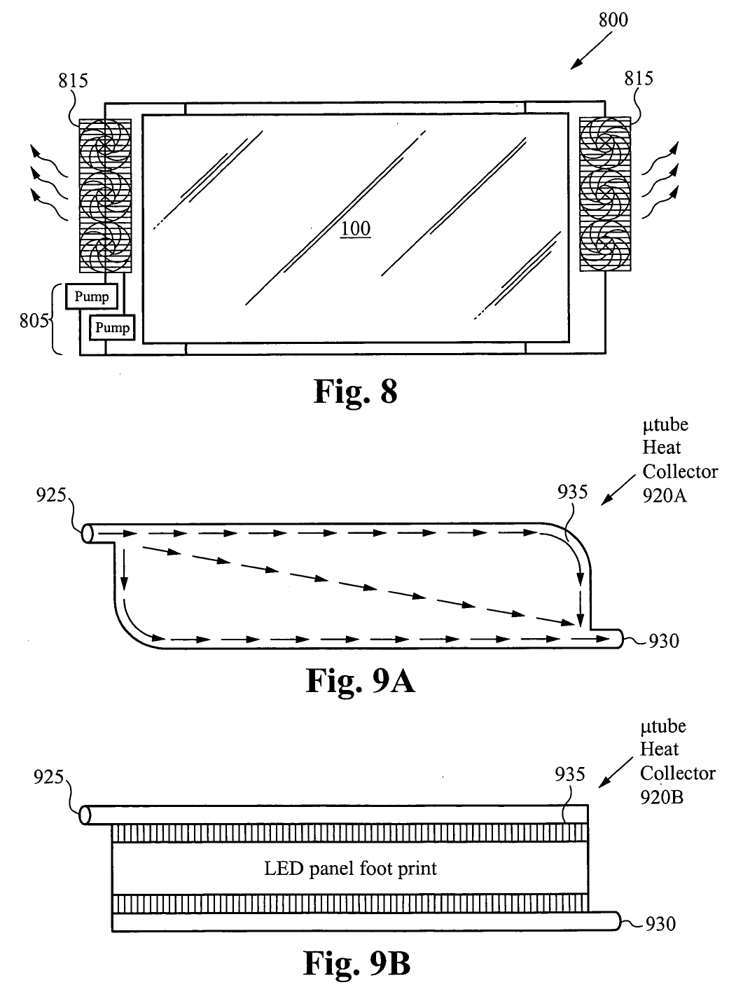

FIG. 8 illustrates another alternative configuration 800 for the cooling system of some embodiments. Specifically, FIG. 8 illustrates that the pump of some embodiments, such as the pump 605 and 705 illustrated respectively in FIGS. 6 and 7, is formed by a coupling of multiple pump devices 805, to optionally provide alternative fluid dynamics to the cooling system 800.

Heat Collector

As mentioned above, some embodiments employ a micro tube heat collector in close contact with the LED array of a display to collect and disperse the heat from the LED array. FIG. 9A illustrates a micro tube heat collector 920A in accordance with some embodiments. As shown in this figure, the heat collector 920 has an inlet 925 and an outlet 930, for the flow of fluid. The heat collector 920A relies upon micro scale heat conduction principles for its operation. An exemplary description of such small scale heat collection principles is described in relation to a heat “exchanger,” in U.S. patent application Ser. No. 10/882,132, entitled “Method and Apparatus for Efficient Vertical Fluid Delivery for Cooling a Heat Producing Device” filed Jun. 29, 2004, which is hereby incorporated by reference.

Owing to the length of the arrays of LEDs, the heat collector of some embodiments could suffer from temperature gradients within the heat collector and undesirable fluid pressure drop. For example, the temperature and pressure in the region most adjacent to the inlet of the heat collector is different than the temperature and pressure of the region that is near the outlet of the heat collector. This has particularly undesirable effects for image display applications because the quality of the displayed image depends in some measure on temperature homogeneity of the LED arrays. Moreover, the temperature at each LED affects its individual performance and useful life.

Some embodiments of the present invention mitigate the temperature difference, from the region adjacent to the inlet to the region near the outlet of the heat collector, by increasing the pressure and/or flow rate at the pump. At sufficiently high flow rates and/or pressures, such as 2.0 liters per minute and/or about 7.0 psi of pressure, for example, the fluid moves quickly enough through the heat collector 920A such that a minimal temperature gradient occurs and any pressure drop does not affect the cooling efficacy of the system. However, as mentioned above, increasing the properties of the pump, such as flow rate and/or pressure, typically has undesirable tradeoffs such as an increase in the cost, noise, and/or the dimensions of the pump, or the other elements of the system, or constrains the type of pumping mechanism for the system. An alternative embodiment contemplates increasing a cross sectional volume of the micro tube to allow more fluid to flow at lower pressures.

Still other embodiments mitigate the temperature difference and pressure drop within the heat collector by using a parallel flow manifold. FIG. 9B illustrates one example of a heat collector 920B that employs a manifold structure having parallel flow according to the invention. As shown in this figure, the heat collector 920B of these embodiments has an inlet 925, an outlet 930, and a series of parallel flow fins 935. Typically, cooled fluid enters through the inlet 925 and flows in parallel through each of flow fins 935, in approximately simultaneous fashion. The flow fins 935 of some embodiments have dimensions in the range of 0.5 to 5.0 millimeters in width by 0.5 to 5.0 millimeters in height. The flow fins can be formed by extrusion of a thermally conductive material such as aluminum or an aluminum alloy. In this manner, fluid flow is more evenly distributed through the heat collector 920B, such that temperature differences between portions of the heat collector 920B are mitigated. Thus, for the exemplary heat collector 920B illustrated in FIG. 9B, the fluid flow is more evenly distributed and the temperature difference is reduced from the left side to the right side of the figure.

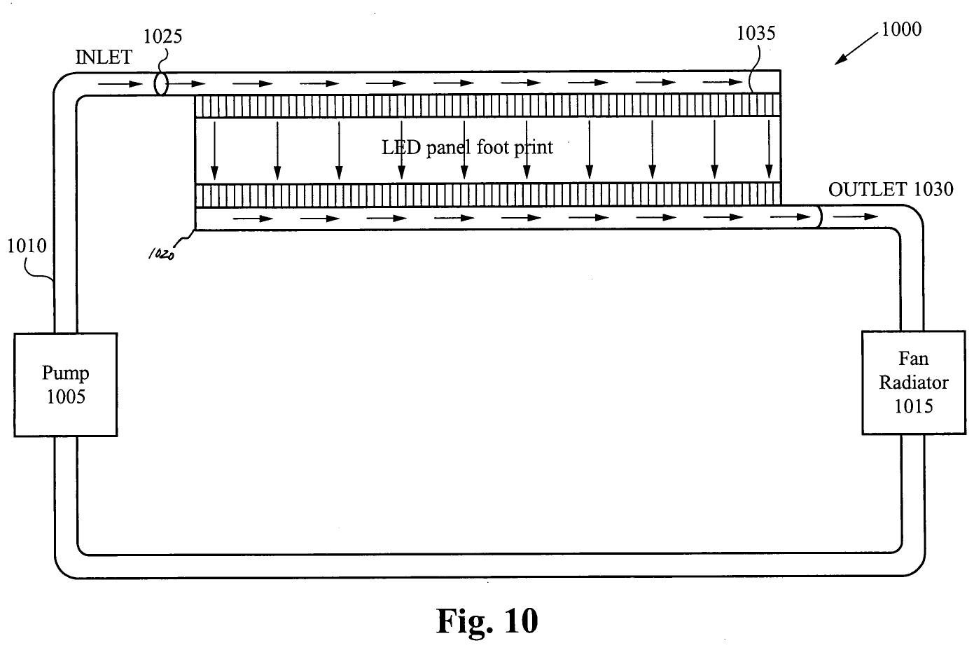

FIG. 10 illustrates the heat collector 920B illustrated in FIG. 9B incorporated into the cooling system of one embodiment. As shown in FIG. 10, the heat collector 1020 is coupled to the LED array of a backlit display. Preferably, the heat collector 1020 is intimately coupled to the LED array to improve the thermal efficiency of the heat transfer from the LED array to the fluid. Most preferably a TIM or thermal grease is used. A fluid inlet 1025 and a fluid outlet 1030 of the heat collector 1020 are coupled to the interconnect tubing 1010 of a cooling system 1000 to form a closed loop. Also shown in FIG. 10, the cooling system 1000 includes a pump 1005 for providing fluid pressure and flow through the loop, and a fan radiator 1015 for dispersion of heat from the fluid.

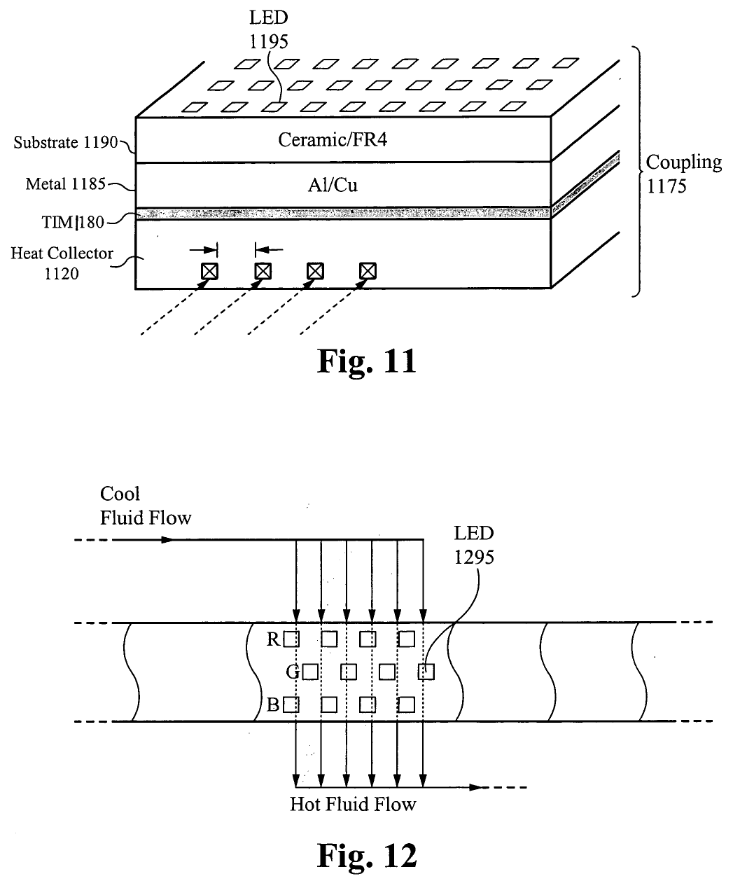

As mentioned above, some embodiments optimize the heat transfer from the LEDs of a display to the heat collector of these embodiments. FIG. 11 illustrates the means by which some embodiments maximize coupling, bonding, and thermal transfer. As shown in this figure, a typical LED display includes a set of LEDs 1195 positioned on an substrate layer 1190, that is in turn disposed on a metal layer 1185. The substrate layer 1190 is typically comprised of an electrical insulator such as a ceramic or FR4 material, for example, while the metal layer 1185 is typically comprised of an aluminum or copper type material. Hence, the metal layer 1185 is capable of heat conductance and/or spreading. Accordingly, some embodiments include a thermal interface material (TIM) layer 1180 between the heat collector 1120 and the metal layer 1185 of the display. The TIM layer 1180 typically comprises an inorganic and/or an organic substance that thermally bonds and transfers heat from the metal layer 1185 of the display's LED arrays to the heat collector 1120. Examples of inorganic thermal interface materials include metallic coat and Indium, while examples of such organic substances include thermal grease, thermal pads, and/or phase change materials. The TIM layer 1180, thus, often has thermally adhesive properties.

Alternatively, the TIM layer 1180 of some embodiments bonds the heat collector 1120 directly to the substrate layer 1190, without the need for the metal layer 1185. Also shown in FIG. 11, some embodiments include a physical coupling means 1175 to mechanically affix the heat collector 1120 to the TIM layer 1180, the metal layer 1185, and/or the substrate layer 1190. The coupling means 1175 includes a variety of mechanical implementations such as, for example, screws, brackets and/or clamping means. By providing a mechanical force to affix the heat collector 1120, to the layers of the backlit device, the coupling means 1175 adds to the structural integrity of the system, and further promotes heat transfer from the device to the heat collector 1120.

As mentioned above, the heat collector 1120 is preferably coupled and/or bonded to the heat source in such a way as to optimize thermal transfer. Some embodiments also orient the flow of fluid through the heat collector 1120 in order to further maximize the conduction of heat via the travel of the fluid. For instance, FIG. 12 illustrates a top view of the fluid flow across a set of hot LEDs 1295 in an array. As shown in this figure, cool fluid is directed through a manifold having a set of vanes that are approximately parallel. Also mentioned above, the maximum pitch between the vanes of some embodiments is in the range of 1.0 to 5.5 millimeters. The cool fluid travels in close proximity to the trichromatic (RGB) LEDs 1295 of the arrays, such that the fluid conducts heat, and carries the heat away from the LEDs 1295.

Method

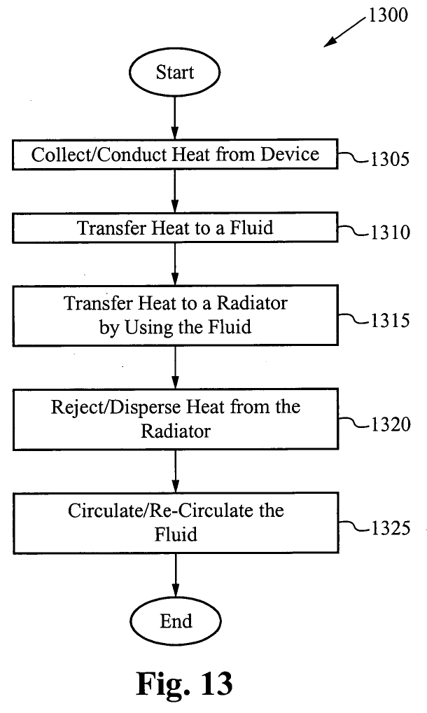

FIG. 13 is a process flow 1300 illustrating the steps of some of these embodiments. As shown in FIG. 13, the process 1300 begins at the step 1305, where the heat from the backlit device is collected in a heat collector. As described above, the heat collector of some embodiments includes a micro tube that has a fluid. Preferably, the micro tube is disposed in intimate contact with the backlit device. In some embodiments, the heat collector comprises two or more parallel flow fins. The flow fins direct the fluid flow in parallel such that the temperature of the heat collector is substantially distributed. Once the heat is collected from the device at the step 1305, the process 1300 transitions to the step 1310, where the heat is transferred to a fluid. Then, the process 1300 transitions to the step 1315.

At the step 1315, the heat is transferred to a radiator by using the fluid, and the process 1300 transitions to the step 1320. At the step 1320, the heat is dispersed or rejected from the radiator and then, at the step 1325, the cooled fluid is circulated and/or re-circulated through the system. After the step 1325, the process 1300 concludes. The (re)circulation of the fluid is typically performed by using a pump. Optionally, excess fluid is stored in a reservoir, which also preferably compensates for any loss of fluid over time.

While the invention has been described with reference to numerous specific details, one of ordinary skill in the art will recognize that the invention can be embodied in other specific forms without departing from the spirit of the invention. Thus, one of ordinary skill in the art will understand that the invention is not to be limited by the foregoing illustrative details, but rather is to be defined by the appended claims.

What is claimed is:

1. A cooling system for a backlit device, the cooling system comprising:
a first heat collector comprising a micro tube, the first heat collector for maintaining contact with the backlit device;
a first radiator for distributing heat;
a first pump for driving a fluid flow;
an interconnect tubing, wherein the interconnect tubing is interposed between the first heat collector, the first radiator, and the first pump to form a closed cooling loop; and
a fluid for conducting heat, the fluid sealed within the closed cooling loop.

2. The cooling system of claim 1, wherein the backlit device comprises an LED backlit flat panel display.

3. The cooling system of claim 2, wherein the flat panel display is an edge type LED backlit display, wherein the LEDs of the edge type display generate a high amount of heat.

4. The cooling system of claim 2, wherein the LEDs generate heat in a range of approximately 100 Watts to 1000 Watts.

5. The cooling system of claim 2, wherein the flat panel display has a thin form factor in a range of approximately 0.5 inches to approximately 4.0 inches in depth.

6. The cooling system of claim 1, wherein the first heat collector comprises an extruded multiport tubing in intimate contact with the backlit device.

7. The cooling system of claim 1, wherein the micro tube has an dimension in a range of 0.5 to 5.0 millimeters in width by 0.5 to 5.0 millimeters in height.

8. The cooling system of claim 1, wherein the first heat collector comprises a plurality of parallel flow vanes, the flow vanes for directing fluid flow in parallel through the first heat collector such that the temperature of the first heat collector is substantially distributed.

9. The cooling system of claim 1, wherein the maximum pitch between the flow vanes is in a range of 1.0 to 5.5 millimeters.

10. The cooling system of claim 1, wherein the first heat collector is bonded to the backlit device by using a thermal interface material (TIM).

11. The cooling system of claim 10, wherein the TIM is comprised of at least one of Iridium, a metallic coat, a thermal grease, a thermal pad, and a phase change material.

12. The cooling system of claim 1, wherein the first heat collector is coupled to the backlit device by using a mechanical means.

13. The cooling system of claim 12, wherein the mechanical means is selected from a set comprising a screw, a bracket, and a clamp.

14. The cooling system of claim 1 further comprising a reservoir for storing fluid within the closed cooling loop.

15. The cooling system of claim 10 further comprising, for rejecting heat from the first radiator, a fan disposed in proximity to the first radiator.

16. The cooling system of claim 10, wherein the reservoir compensates for fluid loss over time.

17. The cooling system of claim 1, wherein the radiator has a thin form factor in a range of 15-50 millimeters thickness.

18. The cooling system of claim 1, wherein the fluid is selected from a set of cooling fluids comprising a glycol, a dielectric, an alcohol, and a water based solution.

19. The cooling system of claim 1, further comprising a second heat collector.

20. The cooling system of claim 1, further comprising a plurality of radiators.

21. The cooling system of claim 1, further comprising a second pump.

22. A method of cooling a backlit device, the method comprising:
disposing a heat collector in intimate contact with the backlit device, the heat collector having a fluid;
collecting, by using the heat collector, heat from the backlit device;
transferring the heat to a radiator by using the fluid;
rejecting the heat from the radiator; and
recirculating the cooled fluid through the heat collector.

23. The method of claim 22 further comprising selecting the fluid from a set of cooling fluids, the set comprising a glycol based fluid, a dielectric solution, an alcohol based fluid, and a water based solution.

24. The method of claim 22, wherein the backlit device comprises a plurality of light emitting diodes (LEDs).

25. The method of claim 22, wherein the backlit device comprises an LED backlit flat panel display.

26. The method of claim 25, wherein the flat panel display is an edge type LED backlit display, wherein the LEDs of the edge type display generate a high amount of heat.

27. The method of claim 25, wherein the LEDs generate heat in a range of approximately 100 Watts to 1000 Watts.

28. The method of claim 25, wherein the flat panel display has a thin form factor in a range of approximately 0.5 inches to approximately 4.0 inches in depth.

29. The method of claim 22, wherein the heat collector comprises a micro tube, the micro tube having the fluid, wherein the heat is transferred from the backlit device to the fluid via the micro tube.

30. The cooling system of claim 29, wherein the micro tube has an internal dimension in a range of 0.5 to 5.0 millimeters in height and 0.5 to 5.0 millimeters in height.

31. The method of claim 22, wherein the heat collector comprises an extruded multiport tubing in intimate contact with the backlit device.

32. The method of claim 22, wherein the first heat collector comprises a plurality of parallel flow vanes, the flow vanes for directing fluid flow in parallel through the first heat collector such that the temperature of the first heat collector is substantially distributed via the passage of the fluid through the flow vanes.

33. The method of claim 22, wherein the maximum pitch between the flow vanes is in a range of 1.0 to 5.5 millimeters.

34. The method of claim 22, wherein the heat collector is bonded to the backlit device by using a thermal interface material (TIM).

35. The method of claim 34, wherein the TIM is comprised of at least one of Iridium, a metallic coat, a thermal grease, a thermal pad, and a phase change material.

36. The method of claim 22, wherein the first heat collector is coupled to the backlit device by using a mechanical means.

37. The method of claim 36, wherein the mechanical means is selected from a set comprising a screw, a bracket, and a clamp.

38. The method of claim 22 further comprising storing the fluid in a reservoir within the closed cooling loop.

39. The method of claim 38, wherein the reservoir compensates for fluid loss over time.

40. The method of claim 22, wherein the radiator has a thin form factor in a range of 15-50 millimeters thickness.

41. The method of claim 22, further comprising a second heat collector.

42. The method of claim 22, further comprising a plurality of radiators.

43. The method of claim 22, further comprising a pump.
